(19) United States
(12) Patent Application Publication
(10) Pub. No.: US 2021/0025939 A1
(43) Pub. Date: Jan. 28, 2021

(54) SYSTEM, METHOD AND COMPUTER PROGRAMME PRODUCT FOR DETECTING PHYSICAL VARIABLES OF AT LEAST ONE COMPONENT OF A TAP-CHANGING TRANSFORMER AND FOR MONITORING THE COMPONENTS OF A TAP-CHANGING TRANSFORMER

(71) Applicant: Maschinenfabrik Reinhausen GmbH, Regensburg (DE)

(72) Inventors: Anatoli Saveliev, Zeitlarn (DE); Karsten Viereck, Regensburg (DE)

(21) Appl. No.: 16/977,829

(22) PCT Filed: Mar. 1, 2019
(86) PCT No.: PCT/EP2019/055193

§ 371 Date: Sep. 3, 2020

(30) Foreign Application Priority Data
Mar. 6, 2018 (DE) 10 2018 105 087.9

(51) Int. Cl. G01R 31/327; H02P 13/06

(52) U.S. Cl. CPC G01R 31/3274; H02P 13/06

(57) ABSTRACT

A system detects physical variables of at least one component of a tapped transformer and monitors the at least one component of the tapped transformer. The system includes a computer in communicating with a measuring instrument, which is in communicating connection with a sensor for reception of the physical variables. The computer receives the physical variables, which are collected in the measuring instrument, as a function of time of the at least one sensor; filters the physical variables as a function of time to generate filtered signals, and creates from the filtered signals a highly resolved envelope representing a signal level of the physical variables; and determines a first limit value curve and a second limit value curve, the position of which is variable in a direction of an ordinate, and the first limit value curve represents the limit value.

### CROSS-REFERENCE TO PRIOR APPLICATIONS

This application is a U.S. National Phase Application under 35 U.S.C. § 371 of International Application No. PCT/EP2019/055193, filed on Mar. 1, 2019, and claims benefit to German Patent Application No. DE 10 2018 105 087.9, filed on Mar. 6, 2018. The International Application was published in German on Sep. 12, 2019 as WO 2019/170554 under PCT Article 21(2).

### FIELD

The present disclosure relates to detecting physical variables of at least one component of a tap-changing transformer and for monitoring the components of a tap-changing transformer.

### BACKGROUND

On-load tap switches (also called “on-load tap changers”, abbreviated as OLTC) are well-known and widely used in the state of the art. They serve for uninterrupted switching over between different winding taps of tapped transformers.

European Patent Specification EP 2 409 398 B1 discloses a device for monitoring tap changers for transformers. Data for the monitoring are obtained by measuring at least one suitable control parameter such as, for example, motor current, motor voltage, torque, motor noises, temperature and switching noises of the tap changer. The device comprises means by which start values of at least one control parameter can be filed as a reference value. In addition, means are provided to compare these values with instantaneous operating actual values and the data sets produced therefrom are supplied to an evaluating unit. A tap changer, which is to be used and the functioning of which is regarded as appropriate, thus free from defects, is used for learning. Different operating states are worked down in a first operation of this changer and reference values determined. These determined reference values are filed in a memory unit. In accordance with a function it is provided that motor noises are detected as much as possible by the vibration pick-up or microphone, whilst another detecting means is mounted in such a way that it picks up virtually only the switching noise and is less influenced by motor noise. Frequency analysis then comes into consideration for the motor noises, whereas the switching noises are analysed by means of an event detector.

U.S. Pat. No. 6,215,408 B1 discloses a method and a device for processing vibroacoustic signals transmitted by a high-voltage switching-over system. The analog vibroacoustic signal is converted into a digital signal. After enhancement the digital signal is smoothed by a conventional filter and afterwards reduced. Re-orientation of the smoothed signal with respect to a reference signature is carried out so as to obtain a re-oriented signal. Values of the time difference generate an alarm if they exceed a limit value. A new reference representing an updated signature is generated from the re-oriented signal. The re-oriented signal is compared with the updated signatures and reference signatures so as to detect progressive change behaviour or a sudden change, for which purpose variances are included.

### SUMMARY

An embodiment of the present invention provides a system that detects physical variables of at least one component of a tapped transformer and monitors the at least one component of the tapped transformer. The system includes: at least one sensor configured to detect the physical variables of the at least one component of the tapped transformer; and a computer in communicating connection with a measuring instrument, which is in communicating connection with the at least one sensor for reception of the physical variables of the at least one component of the tapped transformer. The computer is configured to: a receive the physical variables, which are collected in the measuring instrument, as a function of time of the at least one sensor; perform data preparation including: filtering of the physical variables as a function of time of the at least one component of the tapped transformer to generate filtered signals, and creating from the filtered signals a highly resolved envelope representing a signal level of the physical variable of the at least one component; and perform data analysis comprising determining a first limit value curve and a second limit value curve, the position of which is variable in a direction of an ordinate, and the first limit value curve represents the limit value.

### BRIEF DESCRIPTION OF THE DRAWINGS

The present invention will be described in even greater detail below based on the exemplary figures. The invention is not limited to the exemplary embodiments. Other features and advantages of various embodiments of the present invention will become apparent by reading the following detailed description with reference to the attached drawings which illustrate the following:

FIG. 1 shows a schematic view of one form of embodiment of the system according to the invention for monitoring components of a tapped transformer;

FIG. 2 shows a schematic view of a further form of embodiment of the system according to the invention for monitoring components of a tapped transformer;

FIG. 3 shows a schematic view of the computer used for the system according to the invention;

FIG. 4 shows a graphical illustration of the recorded signal of the vibrations in the case of a changeover, which is executed by the tap changer, of the tapped transformer from a current tap to an adjacent tap and an envelope generated therefrom;

FIG. 5 shows a graphical illustration of a simplified form of the envelope which is illustrated in FIG. 4 and formed, for example, from fifty support points;

FIG. 6 shows a graphical illustration of one possible form of embodiment of a function which can be used for expansion (widening) the envelope of FIG. 5;

FIG. 7 shows a graphical illustration of the use of the function of FIG. 6 on some of the support points of the envelope of FIG. 5;

FIG. 8 shows a graphical illustration of the use of the function of FIG. 6 on all support points of the envelope of FIG. 5 and for determination of an expanded envelope;

FIG. 9 shows a reproduction of a tracking analysis of the switching noise of a tap changer, which is in operation, on a monitor;

FIG. 10 shows an illustration of the result of the tracking analysis of the switching noise of one of the tap changers on a display associated with the tapped transformer; and

FIG. 11 shows a flow chart of the method according to the invention.

### DETAILED DESCRIPTION

The present invention relates to a system for detecting physical variables of at least one component of a tapped transformer and for monitoring at least one component of a tapped transformer. At least one sensor serves for detection of at least one physical variable of the at least one component of the tapped transformer. A computer is in communicating connection with a measuring instrument, which itself is in communicating connection with the at least one sensor for reception of the at least one physical variable of the at least one component of the tapped transformer.

In addition, the invention relates to a method for monitoring at least one component of a tapped transformer. At least one sensor is provided for detection of physical variables as a function of time.

Equally, the invention relates to a computer program product for monitoring at least one component of a tapped transformer.

It Accordingly, the present invention provides a system for detection of physical variables of at least one component of a tapped transformer and for monitoring the at least one component of the tapped transformer, which system is robust and enables, through a dynamic of the determined limit values, reliable detection of a fault in the load changeover.

Further, the present invention provides a method of monitoring at least one component of a tapped transformer, which method is robust and enables dynamic adaptation of the determined limit values, which leads to reliable detection of a fault with the at least one component.

In addition, the present invention further provides a computer program product for monitoring at least one component of a tapped transformer, which product is robust and enables dynamic adaptation of the determined limit values, which leads to a reliable detection of a fault of the at least one component.

The system according to an embodiment of the present invention for detecting physical variables of at least one component of a tapped transformer and for monitoring the at least one component of a tapped transformer is provided with at least one sensor for detecting the physical variables of the at least one component of the tapped transformer. A computer is communicatively connected with a measuring instrument, which is communicatively connected with the at least one sensor for reception of the physical variables of the at least one component of the tapped transformer. The system comprises a receiving region which is configured for reception of the physical variables collected in the measuring instrument as a function of time of the at least one sensor. Filtering of the physical variables as a function of time of the at least one component of the tapped transformer is carried out in a data preparation region. A highly resolved envelope representing a signal level of the physical variable of the at least one component is created from the filtered signals. A first limit value curve and a second limit value curve, the position of which in the direction of an ordinate is variable, are determined in a data analysis region and the first limit value curve represents a limit value.

A number of components of a tapped transformer can be monitored by the system according to an embodiment of the present invention. The components of the tapped transformer are, for example, an on-load tap changer, the selector, the motor drive of the on-load tap changer, fans and fan motors, which are associated with the tapped transformer, the transformer housing, or the oil in the transformer housing.

Without being perceived as a limitation of the invention, the at least one component can be an on-load tap changer with a motor drive. The motor drive serves for setting different switching positions of the on-load tap changer. The at least one sensor serves for detecting mechanical vibrations caused during the switching process of an on-load tap changer. In that case, the at least one sensor does not necessarily have to be mounted on the on-load tap changer.

A sensor configured in the form of, for example, an acceleration sensor can be sufficient for picking up solid-borne sound.

The system according to the invention has the advantage that a highly modern automatisation platform usable for detection and evaluation of all relevant operating data of a tapped transformer is provided. Thus, operation, maintenance and exchange of operating means of the tapped transformer can be planned more efficiently and in more focused manner. The tapped transformer can be reliably monitored from the data obtained by the at least one sensor.

In the case of the method according to an embodiment of the present invention for monitoring at least one component of a tapped transformer at least one sensor is provided in or at the tapped transformer, wherein the at least one sensor serves for detection of physical variables as a function of time.

In the first instance, the physical variables are detected by the at least one sensor by a measuring instrument. The recorded analog physical variables are transferred from the measuring instrument to a receiving region of the computer. The detected physical variables are filtered in a data preparation region and converted into a digital highly resolved envelope. An envelope is obtained from the highly resolved envelope by means of a data reduction.

A first limit value curve and a second limit value curve are determined in a data analysis region on the basis of the envelope for each physical variable. The first limit value curve and the second limit value curve are updated on the basis of envelopes for subsequently measured physical variables by way of the first limit value curve and the second limit value curve for previously measured physical variables. The first limit value curve represents a limit value.

The recorded signal of the measured physical variable of the at least one component of the tapped transformer undergoes filtering. The filtered physical variables are converted into digital data. According to a preferred form of embodiment of the method according to the present invention, the filtering is a low-pass filtering of the recorded physical variables, which serves to avoid alias effects. The filtered physical variables are converted into digital signals that yield a highly resolved envelope. Fresh low-pass filtering is used on the highly resolved envelope and the filtered digital signal undergoes data reduction.

Determination of the envelope curve is carried out by way of a number of support points, which are determined on the basis of the highly resolved envelope curve. Prior to determination of the first and second limit value curves, the envelope is spread in such a way that a function is set at each support point. A downwardly open asymmetrical function is preferably set at each support point of the envelope. In particular, the function can be a downwardly open parabola. A further possible feature of the parabola can be that it is narrower on the left than on the right. The use of a parabola is not to be interpreted as a limitation of the invention. Other functions such as, for example, asymmetrical functions can also be used at the support points.

After spreading of the envelope, a fresh calculation of the second limit value curve is performed. Updating of the two limit value curves can be undertaken by the newly calculated second limit value curve. Equally, there is the possibility of not including every envelope in the calculation of the second limit value curve. This is the case, for example, when a one-time event is suddenly revealed in the envelope. If this event should occur multiple times in succession, the envelope is included in the calculation of the second limit value curve and in a given case an alarm for a faulty function is triggered.

According to a preferred form of embodiment and without being interpreted as a limitation of the present invention, the at least one component of the tapped transformer is an on-load tap changer. The on-load tap changer serves for setting different switching positions of the tapped transformer. For that purpose, a motor drive for driving of the on-load tap changer and at least one sensor for detection of mechanical vibrations caused by a switching process of the on-load tap changer are associated with the tapped transformer. The arrangement of the sensors can be at any desired positions of the on-load tap changer or the tapped transformer.

The at least one sensor can be an acceleration sensor for detection of mechanical vibrations. The acceleration sensor records, as a function of time, the solid-borne sound signal caused by a switching process of the on-load tap changer.

The advantage of the method is therefore that all relevant operating data of a tapped transformer can be detected. Thus, operation, maintenance and exchange of operating means of the tapped transformer can be planned more efficiently and in more focused manner. The tapped transformer can be reliably monitored from the data obtained by the at least one sensor and the determined limit values are dynamically set.

Equally, the idea according to the invention can be realised by a computer program product that comprises a plurality of program instructions which on execution of the program instructions by a computer cause the computer to perform the steps of the method according to the invention.

The method according to the invention can preferably be used for monitoring on-load tap changers of a tapped transformer. An on-load tap changer in the case of a switching process generates characteristic sound signatures, which, for example, can be recorded by way of acceleration sensors and evaluated by a computer. However, in the case of recording the solid-borne sound, the noises of, for example, the active part and the cooling installation of the tapped transformer are additionally subject to superimposition by the noises of the on-load tap changer when switching. In the case of an on-load tap changer, individual sound signatures of the load changeover switch are determinative for the type of tap changer. In their course over time and amplitude they characterise the mechanical operating state of the respective on-load tap changer.

According to one possible form of embodiment, the acceleration sensor can be mounted on the head of the on-load tap changer. Other mounting locations such as, for example, on the transformer housing or within the transformer housing are also possible. The high resolution of the sound signal by the acceleration sensor gives rise, in subsequent analog-to-digital conversion in the system, to a correspondingly high volume of data. This data set, apart from the noise of the tap changer, can also reproduce the noise of the active part of the tapped transformer by fundamental waves and harmonic waves before and after a switching process. An envelope is created from the high-frequency components of the data set. The known different kinds of switching of the on-load tap changer such as, for example, reverse switchings (from an output tap to a tap and back to the output tap), preselector switchings or switchings in the end position of the on-load tap changer, can generate envelopes of different appearance.

The vibroacoustic method according to the invention in that case represents a pragmatically functioning method with low resolution and is also termed tracking method in the following.

In that case, each switching of the on-load tap changer is checked with regard to whether it matches the stored historical data set. In the system according to the invention a self-learning algorithm was used simultaneously with the acoustic monitoring. A ‘learning’ system or ‘learning’ method is created by the invention: the data set of the first and second limit value curves is not merely data stored once. The first and second limit value curves are continuously determined on the basis of a number of preceding switching actions of the on-load tap changer. The first and second limit value curves contain historical data sets which can be additionally weighted. Only after a certain number of switchings (events) are the first and second limit value curves ascertained for determining the limit value.

The measurement values are recorded for each switching of the on-load tap changer. For evaluation of the switchings of the on-load tap changer, in the context of the signal preparation the significant part of the data set is reduced to approximately one hundred support points for generating the envelope. The number of support points is not to be interpreted as a limitation of the invention. Thus, for example, the number of support points can vary depending on computing performance of the computer.

With the assumption of a Gaussian probability distribution, the significant peaks of the recorded envelopes are subsequently expanded. The envelope is additionally checked for plausibility and in a given case not included in the computation of the first and second limit value curves. As a result, with historical data, the expansion of the envelope and/or a displacement on the ordinate and taking into consideration the statistics of the preceding switching actions there is created a first limit value curve by way of the peaks, which characterise the tap changer switching, of the envelope of the acoustic sound signal. A singular freak value is thus not taken up in the computation of the limit value curves.

At the same time, there is produced from the statistics a second limit value curve which lies thereabove and which represents an even higher limit value for the acoustic signal.

The first and second limit value curves are independently determined on the basis of the stored historical data of the system. Use is made for that purpose of statistical methods.

The invention and its advantages are described in more detail in the following with reference to the accompanying drawings.

Identical reference numerals are used for the same or equivalent elements of the invention. In addition, for the sake of clarity there is illustration in the individual figures of only reference numerals required for the description of the respective figure. The illustrated forms of embodiment represent merely examples of how the system according to the invention, the method according to the invention or the computer program product according to the invention can be designed.

The following description refers to a system and a method for detecting solid-borne sound of an on-load tap changer of a tapped transformer. Limitation of the following description to determination of limit value curves from the measured solid-borne sound of an on-load tap changer is not to be interpreted as limitation of the invention. It will obvious to an expert that a number of different components of a tapped transformer can be monitored by methods according to the invention.

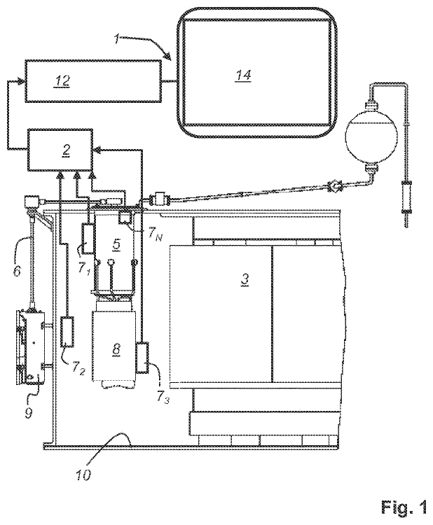

FIG. 1 shows a schematic view of one form of embodiment of the system according to the invention for monitoring components of a tapped transformer 3. The tapped transformer 3 is surrounded by a transformer housing 10. The different winding taps of the tapped transformer 3 can be connected by an on-load tap changer 5. In order to be able to ensure correct functioning of the tapped transformer 3 the on-load tap changer 5 has to execute the required switching sequence without disturbances. In order to be able to recognise ageing processes of the on-load tap changer 5 and/or of the tapped transformer 3 as early as possible and in a given case to be able to initiate servicing measures at least one sensor 7₁, 7₂, 7₃ . . . 7_{N} which detects the vibroacoustic vibrations of the on-load tap changer 5 as a consequence of the switching processes is provided. The on-load tap changer 5 projects into the transformer housing 10 which, depending on the type of the tapped transformer 3, is filled with oil. The at least one sensor 7₁, 7₂ . . . 7_{N} can be associated with the on-load tap changer 5, the selector 8 thereof and/or a motor drive 9. The at least one sensor 7₁, 7₂ . . . 7_{N} is in general designed as a sound/vibration pick-up such as, for example, a hydrophone in oil, microphone, piezo disc in oil, acceleration sensor or vibration sensor. In the case of the embodiment illustrated here the drive movement of the motor drive 9 is transferred by way of a linkage 6 to the on-load tap changer 5 or to the associated selector 8. The at least one sensor 7₁, 7₂ . . . 7_{N} is connected with a measuring instrument 2, which collects the signals of the sensors 7₁, 7₂ . . . 7_{N}.

The signals received from the at least one sensor 7₁, 7₂ . . . 7_{N} are transferred by way of the measuring instrument 2 to a computer 12. The signals can be processed and worked therein. In the form of embodiment illustrated in FIG. 1 the computer 12 is positionally associated with the transformer housing 10.

Equally, it is conceivable for the signals to be transmitted by the at least one sensor 7₁, 7₂ . . . 7_{N} to the computer 12, in which case for that purpose all usual possibilities of transmission are utilisable so that evaluation of detected signals at a positionally remote observation point, for example a service centre, takes place. A monitor 14 or user interface is associated for visualisation of the signals received from the at least one sensor 7₁, 7₂ . . . 7_{N} and processed by the computer 12.

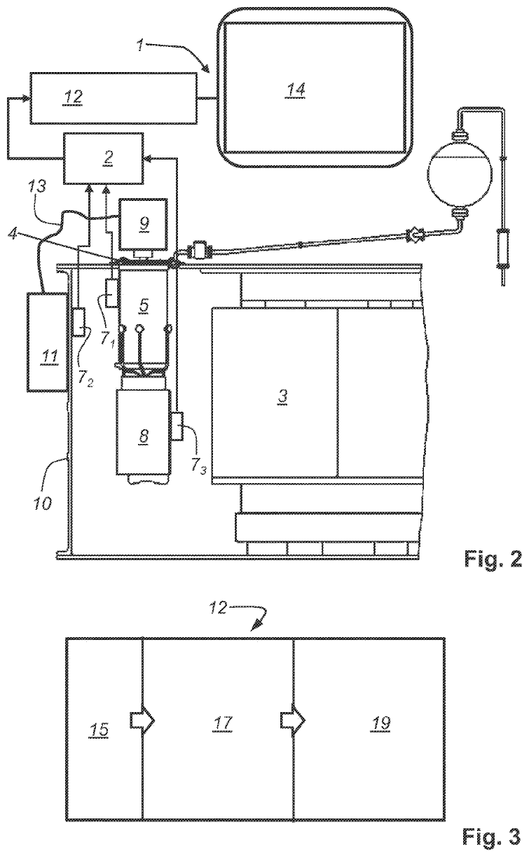

FIG. 2 shows a further form of embodiment of the arrangement of the motor drive 9 for the on-load tap changer 5 or selector 8. The motor drive 9 is associated, outside the transformer housing 10, directly with the on-load tap changer 5. A control 11 for the motor drive 9 is provided at the transformer housing 10. The control signals from the control 11 are conducted by way of, for example, a cable connection 13 to the motor drive 9. The system 1 comprises a plurality of sensors 7₁, 7₂ . . . 7_{N} which in the case of the form of embodiment illustrated here are associated with, for example, the on-load tap changer 5, the selector 8 or the transformer housing 10. The at least one sensor 7₁, 7₂ . . . 7_{N} has communicating connection with the measuring instrument 2. The measured signals are transferred from the measuring instrument 2 to a computer 12. As a rule, the computer 12 and the monitor 14 are arranged in the vicinity of the transformer housing 10. However, this is not to be interpreted in the least way as a limitation of the invention.

If in the evaluation of the detected signals in the form of embodiment of FIG. 1 or FIG. 2 a difference is ascertained, an alarm report can be triggered by way of the system. The alarm report can be output on, for example, the monitor 14. Other possibilities of output of the warning report are conceivable.

The layout of the computer 12 is schematically illustrated in FIG. 3. The computer comprises at least one receiving region 15, data processing region 17 and data analysis region 19. In the receiving region 15 the signals received from the at least one sensor 7₁, 7₂ . . . 7_{N} are collected, which are communicatively connected with the receiving region 15 of the computer 12. The at least one sensor 7₁, 7₂ . . . 7_{N} can be constructed as, for example, an acceleration sensor. From the measuring unit 15, the detected signals are transferred to a data processing region 17 of the computer 12. The signals are initially received in the data processing region 17. The supplied signals (raw data) are filtered and converted into digital data. An envelope is created from the digital data. The envelope has high resolution.

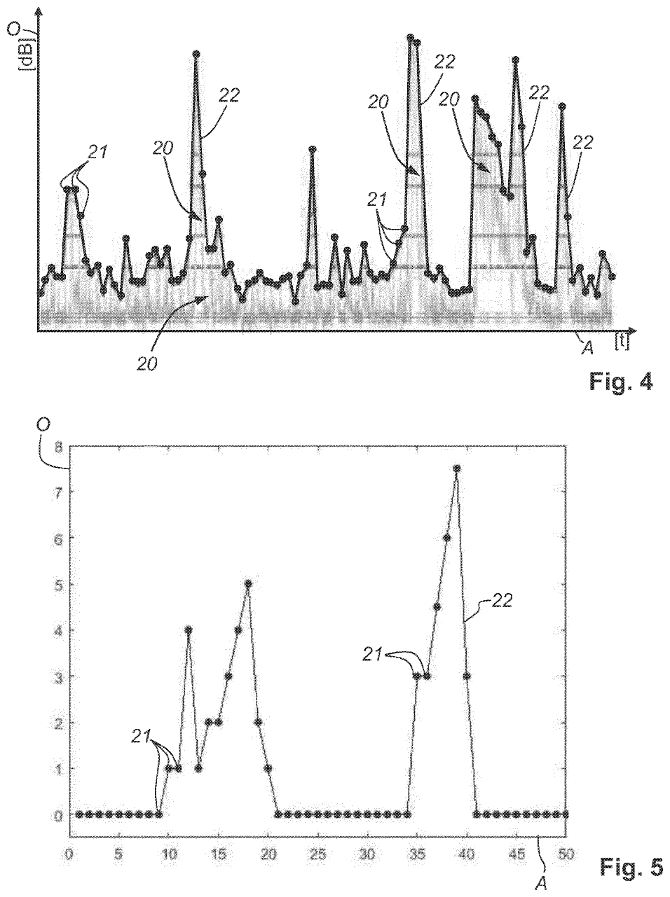

FIG. 4 shows a graphical illustration of the signal which is recorded by the at least one sensor 7₁, 7₂ . . . 7_{N} and which has already been converted into a highly resolved envelope 20 of the vibrations. The vibrations arise at the time of a switching over, which is executed by the on-load tap changer 5, of the tapped transformer 3 from a current tap to an adjacent tap and there is generated from the highly resolved envelope 20 an envelope 22 which is formed with a reduced number of measuring points. For determination of the envelope 22, a plurality of support points 21 which ultimately define the envelope 22 is determined from the highly resolved envelope 20. The at least one sensor 7₁, 7₂ . . . 7_{N} for picking up the vibrations (solid-borne sound) can be, for example, an acceleration sensor. The time in desired units is recorded on the abscissa A. The signal strength in decibels (dB) is recorded on the ordinate O. The highly resolved envelope 20 shown in FIG. 4 and the envelope 22 are determined on each occasion of the tap changer switching. Each tap changer switching is then checked as to whether it matches the stored historical data set (first limit value curve or second limit value curve). In that case, for creating the envelope 20 the significant part of a data set of the highly resolved envelope 20 is reduced to approximately one hundred supports points 21 (as already explained above, the number of support points 21 is not to be interpreted as a limitation of the invention).

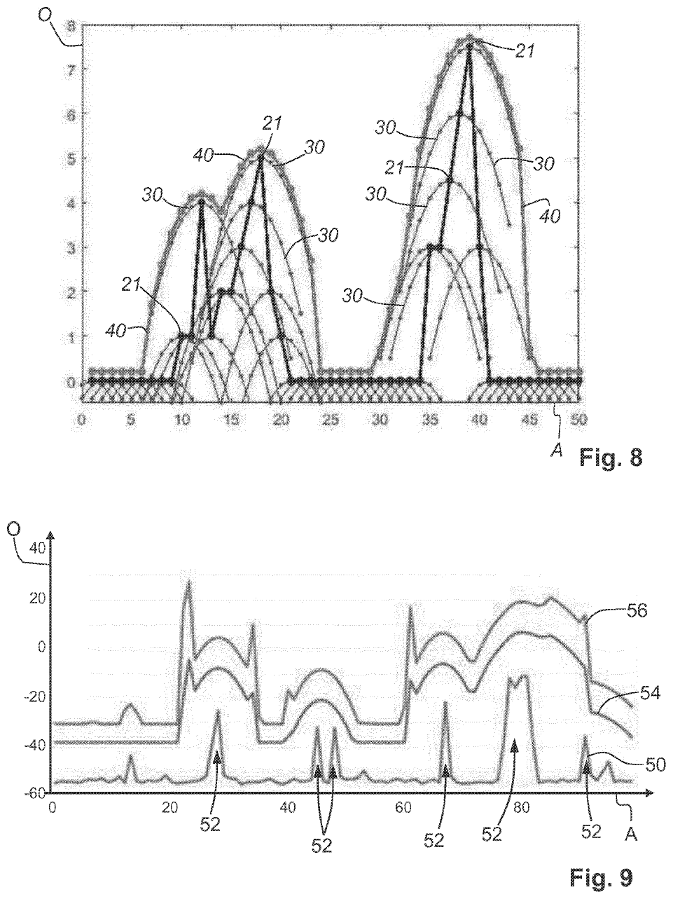

FIG. 5 shows a graphical illustration of a simplified form of the envelope 22 illustrated in FIG. 4. The envelope 22 in the example illustrated here is formed from fifty support points 21 and shown so as to illustrate the acquisition of the limit value curves 54, 56 (see FIG. 8 or 9). The time is recorded on the abscissa A and the signal is recorded on the ordinate O.

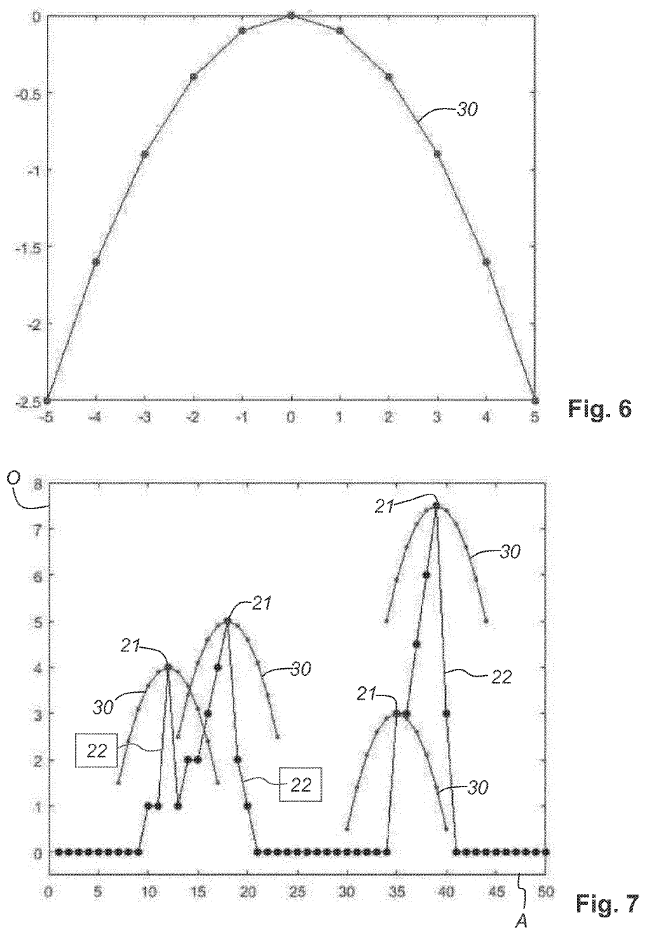

FIG. 6 shows a graphical illustration of one possible form of embodiment of a function 30 which can be used for widening (expanding) the envelope 22 of FIG. 4. In the case of the form of embodiment illustrated here, the function 30 is a parabola (a quadratic function, which can be used for the expansion). The form of the function 30 is not to be interpreted as a limitation of the invention. The use of the function (parabola) of FIG. 5 is illustrated in FIG. 7. The function 30 is placed at some of the support points 21 of the envelope 22.

FIG. 8 shows a graphical illustration of the use of the function 30 of FIG. 5 at all support points 21 of the envelope 22 of FIG. 4. A resultant signal curve 40 is obtained by the use of the function 30 at all support points 21 of the envelope 22. The resultant signal curve 40 is offset somewhat in the direction of the ordinate O so that the resultant signal curve 40 can be more easily seen. The resultant signal curve 40 is used for determination of the limit values. As already mentioned, the form of the function 30 can differ from a quadratic function. In that case it is to be noted that the function 30 is selected with consideration of the signal shape and the nature of anticipated changes. The shape of the function 30 can, but does not have to, be symmetrical. Equally, the shape of the function 30 can be flexibly arranged to be variably dependent not only on time, but also on signal strength or other parameters.

FIG. 9 shows a reproduction of a tracking analysis of the switching noise of an on-load tap changer 5 in operation, such as can be illustrated in accordance with FIG. 9 on a monitor 14.

In that case, each switching sequence of the on-load tap changer 5 is checked as to whether it matches the stored historical data set. As in the case of cluster analysis, the database for that is checked for each switching sequence of the on-load tap changer 5 on the basis of the signal level 50 of each switching sequence of the on-load tap changer 5. The signal level 50 is obtained from the measurement data (signals) of a switching sequence of the on-load tap changer 5, in which case, as described in FIG. 3, the envelope 22 represents the signal level 50. The significant part of the measurement data (data set of the signals) is reduced to approximately one hundred support points 21 for the signal processing, so as to produce the envelopes or signal level 50.

The recorded and determined envelope 22 is initially compared with the first limit value curve 54 and the second limit value curve 56. If the envelope 22 is in order, then (as illustrated in FIG. 8) it is expanded and utilised for limit value formation (first and second limit value curves 54, 56) for analysis of the subsequent switching-over processes for every point of the expanded envelope 22 on the assumption of Gaussian probability distribution (which is determined by way of several measurements, switching-over processes). As a result thereof, a first limit value curve 54 by way of the characteristic peaks 52 of the signal level 50 arises. At the same time, a second limit value curve 56 lying thereabove is generated from the statistics thereof, the second limit value curve representing a higher limit value for the acoustic signal of the on-load tap changer 5. The currently applicable limit value curves 54, 56 are used for evaluation of the currently recorded physical variables (here solid-borne sound). The current measurement of physical variables is not utilised for limit value computation. If the measurement of the physical variables was found to be good, the limit value curves 54, 56 are recalculated with consideration of the current envelope 22 as well as the preceding and defined limit value curves 54, 56 for the future measurements of the physical variables.

The resultant first limit value curve 54 is used as limit value and at the same time utilised for flexible adaptation of the just still permissible amplitude range of the acoustic signal. The first limit value curve 54 and the second limit value curve 56 are thus redrawn. By virtue of this tracking method, the system iteratively learns, during switching of the on-load tap changer 5, how an acoustic signal of a correctly functioning on-load tap changer 5 appears, so as to check by the self-generated signal level 50 (envelope 22) all subsequent switching actions of the on-load tap changer 5 with respect to the correct sequence thereof

The system for monitoring components of a tapped transformer 3 generates at least the first and second limit value curves 54 and 56 for each kind of switching. It can thus be checked for each new switching of the on-load tap changer 5 whether the respective on-load tap changer 5 still operates within the permissible scope with regard to the amplitude of the switching noise and the time sequence of the switching. If a difference is ascertained, an alarm report can be triggered by way of the system.

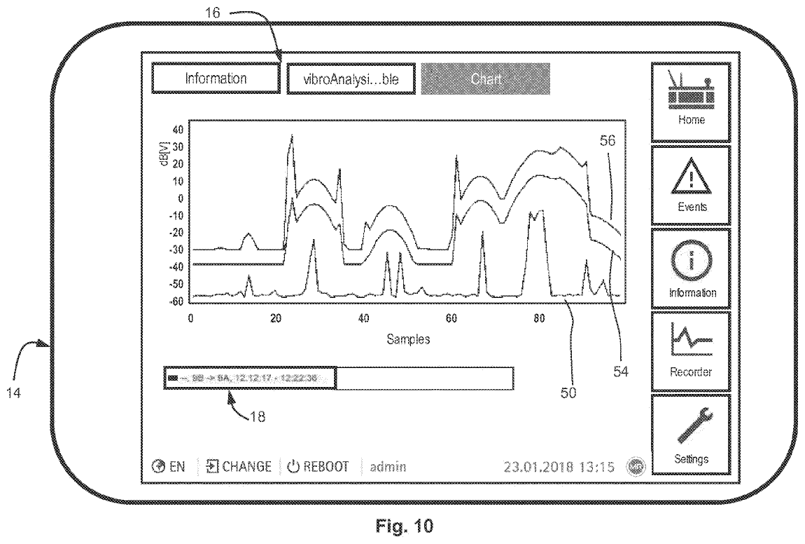

FIG. 10 shows an illustration of the result (see FIG. 8) of the tracking analysis of the switching noise of the on-load tap changer 5. In this embodiment, the monitor 14 is associated with the tapped transformer 3. The monitor 14 comprises a display 16 on which the evaluation of the switching noise of the on-load tap changer 5 can be illustrated. The signal level 50 (in the processed form with peaks 52) illustrated and measured in FIG. 8 is illustrated on the display 16. Equally, the limit value curves 54, 56 determined from the signal level 50 or on the basis of the signal level 50 from the preceding switching of the on-load tap changer are illustrated. As a result, the history of the previous switchings of the on-load tap changer are utilised in the calculation of the limit value curves 54, 56. Information on from which switching sequence of the on-load tap changer 5 the signal level 50 was generated can be given to a user or checking operative in a field 18 on the display 16. Here it can be notified, for example, by means of the field 18 that the switching-over of the on-load tap changer 5 from the tap with No. 9B to the tap with No. 9A took place. In addition, date and clock time of the switching-over process are also illustrated. The limit value curves 54, 56 are regenerated for each new switching kind of the on-load tap changer 5 from the newly determined signal level 50. It can be thus checked whether the respective on-load tap changer 5 still operates within the permissible scope with respect to the amplitude of the switching noise and time sequence of the switching. The limit value curves 54, 56 are independently determined on the basis of the stored historical data of the system 1. Statistical methods are used for that purpose.

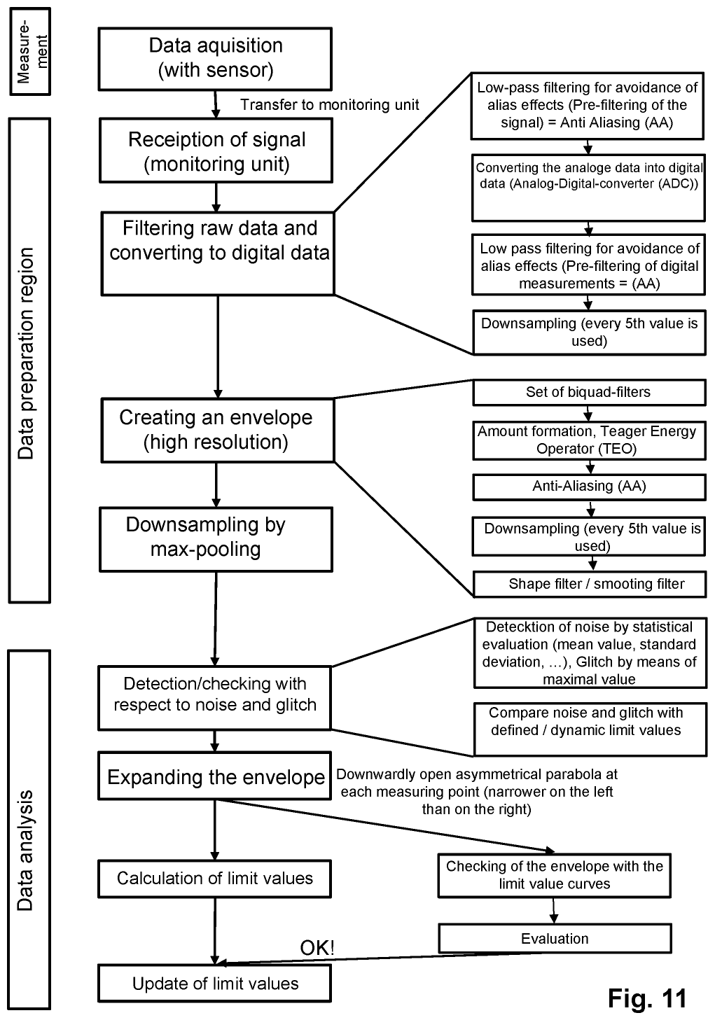

FIG. 11 shows a flow chart of the method according to the invention for monitoring at least one component of a tapped transformer. The method according to the invention is, as shown in FIG. 2, used in a system 1 which makes available drive energy where it is needed. In this embodiment the motor drive 9 is provided on, in particular, a cover 4 (illustrated in FIG. 2) of the on-load tap changer 5. The transmission of the drive commands generated in the control 11 for the motor drive 9 takes place by means of a cable connection 13.

The signals or the measured physical variables are automatically picked up by the at least one sensor 7₁, 7₂ . . . 7_{N} in a switching process of the on-load tap changer. The evaluation and analysis of the data makes possible a monitoring unit of the on-load tap changer 5 on site (at the on-load tap changer 5 itself). The computer 12 and/or the display 16 of the monitor 14 can be accommodated at the transformer housing 19 of the tapped transformer 3, in a cabinet at the transformer housing 19, at a central station or the like. The at least one sensor 7₁, 7₂ . . . 7_{N} can be constructed as an acceleration sensor. The measurement values (solid-borne sound) from the switching-over process of the on-load tap changer are automatically detected by the acceleration sensor and communicated to the computer 12 by way of a communicative connection. The detected measurement values are prepared in the data preparation region 17 in the mode and manner according to the invention.

Filtering of the raw data (measured analog signals) is subsequently undertaken in the data preparation region 17. Ultimately, the appropriately processed data are converted by an analog-to-digital converter of the computer 12 into digital data.

The filter of the data preparation region 17 in the first instance comprises a low-pass filter for avoidance of alias effects. This represents pre-filtering of the analog signal, which produces anti-aliasing (AA) or edge smoothing. The analog signals filtered by low-pass filtering are converted by means of an analog-to-digital converter (ADC) into the digital highly resolved envelope 20. A repeated low-pass filtering is applied to the high-resolution envelope 20 for avoidance of alias effects (pre-filtering of the digital measurement values). Finally, a data reduction (downsampling) of the digital signal is carried out.

A high-resolution envelope 20 is created from the filtered and digital signals. A correspondingly reduced envelope 22 is generated for each switching process of the on-load tap changer 5. In order to create the high-resolution envelope 20, a set of biquad filters, an amount formation, an anti-aliasing (AA), a downsampling and a shape filter / smoothing filter are used on the digital signals.

A further downsampling by means of max-pooling is carried out on the data, which is obtained by the data preparation, for the highly resolved envelope 20. The envelope 22 is the result.

Subsequently thereto, a data analysis is carried in a data analysis region 19. Initially, a detection/checking of the run-outs of the envelope 22, i.e. the regions before and after the switching-over process of the on-load tap changer, where normally no signals are present, is checked with respect to noise and glitch. The noise is detected by means of, for example, statistical evaluation (mean value, standard deviation, . . . ). The glitch is detected by means of a maximum value. The detected noise and the glitch are compared with defined/dynamic limit values. Excessive noise and values of the glitch signify external influencing (for example rain, hail). In these conditions, either the analysis of the signal is carried out only to a limited extent or an analysis of the signal is dispensed with entirely.

The envelope 22 is subsequently expanded. For that purpose, in accordance with one possible form of embodiment, as already mentioned a downwardly open asymmetrical function 30 can be set at each support point 21 (measuring point). This function 30 can be, for example, a parabola which is narrower on the left than on the right.

After the expansion of the envelope 22 the calculation (update of statistics) is thus carried out. An updating of the limit value curves 54, 56 can be performed with the recalculated statistical data.

In the first instance, checking of the envelope 22 with the existing plots of the limit value curves 54, 56 can be carried out. Subsequently, evaluation of the check is performed and if this was found to be in order an updating of the limit value curves 54, 56 can be similarly undertaken.

While embodiments of the invention have been illustrated and described in detail in the drawings and foregoing description, such illustration and description are to be considered illustrative or exemplary and not restrictive. It will be understood that changes and modifications may be made by those of ordinary skill within the scope of the following claims. In particular, the present invention covers further embodiments with any combination of features from different embodiments described above and below. Additionally, statements made herein characterizing the invention refer to an embodiment of the invention and not necessarily all embodiments.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### REFERENCE NUMERAL LIST

1 system
2 measuring instrument
3 tapped transformer
4 cover
5 on-load tap changer
6 linkage
7₁, 7₂ . . . 7_{N} sensor
8 selector
9 motor drive
10 transformer housing
11 control
12 computer
13 cable connection
14 monitor
15 receiving region
16 display
17 data preparation region
18 field
19 data analysis region
20 highly resolved envelope
21 support points
22 envelope
30 function
40 resultant signal curve
50 signal level
52 peak
54 first limit value curve
56 second limit value curve
A abscissa
O ordinate

1. A system for detection of physical variables of at least one component of a tapped transformer and for monitoring the at least one component of the tapped transformer, the system comprising:
at least one sensor configured to detect the physical variables of the at least one component of the tapped transformer; and
a computer in communicating connection with a measuring instrument, which is in communicating connection with the at least one sensor for reception of the physical variables of the at least one component of the tapped transformer, wherein the computer is configured to:
a receive the physical variables, which are collected in the measuring instrument, as a function of time of the at least one sensor;
perform data preparation comprising: filtering of the physical variables as a function of time of the at least one component of the tapped transformer to generate filtered signals, and creating from the filtered signals a highly resolved envelope representing a signal level of the physical variable of the at least one component; and
perform data analysis comprising determining a first limit value curve and a second limit value curve, the position of which is variable in a direction of an ordinate, and the first limit value curve represents the limit value.

2. The system according to claim 1, wherein the at least one component is an on-load tap changer with a motor drive configured to set different switching positions of the on-load tap changer, wherein the at least one sensor is configured to detect mechanical vibrations caused by an on-load tap changer in the switching process.

3. The system according to claim 2, wherein the at least one sensor comprises an acceleration sensor.

4. A method for monitoring at least one component of a tapped transformer, wherein at least one sensor for detection of physical variables as a function of time is provided, the method comprising:
detecting the physical variables by the at least one sensor by a measuring instrument;
transferring the physical variables from the measuring instrument to a receiver of a computer;
filtering the detected physical variables to generate filtered signals;
converting the filtered signals into a digital highly resolved envelope;
generating an envelope obtained by data reduction from the digital highly resolved envelope;
determining a first limit value curve and a second limit value curve on the basis of the envelope for each of the physical variables; and
updating the first limit value curve and the second limit value curve on the basis of envelopes for subsequently measured physical variables by way of the first limit value curve and the second limit value curve for previously measured physical variables.

5. The method according to claim 4, the method further comprising filtering the measured physical variable of the at least one component of the tapped transformer and converting the filtered physical variables into digital data.

6. The method according to claim 5,
wherein the filtering the measured physical variables comprises a low-pass filtering of the physical variables for avoidance of alias effects,
wherein the converting the filtered physical variables into digital data yields the digital highly resolved envelope, and
wherein generating the envelope comprises: low-pass filtering the digital highly resolved envelope to generate a filtered digital signal, and performing the data reduction on the filtered digital signal.

7. The method according to claim 4, wherein the envelope is determined by way of a plurality of support points which are ascertained on the basis of the digital highly resolved envelope.

8. The method according to claim 4, wherein the envelope is prepared in such a way that a function is set at every support point.

9. The method according to claim 8, wherein the function set at every support point of the envelope is a downwardly open asymmetrical function (30).

10. The method according to claim 4, the method comprising, after spreading of the envelope, performing a calculation of the second limit value curve, and
wherein updating of the limit value curves is carried out with the newly calculated second limit value curve.

11. The method according to claim 4, wherein the at least one component of the tapped transformer is an on-load tap changer which is configured for setting different switching positions of the tapped transformer, and a motor drive driving of the on-load tap changer and at least one sensor for detecting the mechanical vibrations caused by a switching process of the on-load tap changer are associated with the tapped transformer.

12. The method according to claim 11, wherein the at least one sensor comprises an acceleration sensor which records the solid-borne sound signal, which is caused by a switching process of the on-load tap changer, as a function of time.

13. A non-transitory computer readable medium comprising a plurality of program instructions which on execution of the program instructions by a computer cause the computer to perform the method according to claim 4.

14. The method according to claim 9, wherein the downwardly open asymmetrical function is a downwardly opened parabola narrower on the left than on the right.
